(19) United States
(12) Patent Application Publication
(10) Pub. No.: US 2022/0157688 A1
(43) Pub. Date: May 19, 2022

(54) DIRECT-COOLING FOR SEMICONDUCTOR DEVICE MODULES

(71) Applicant: SEMICONDUCTOR COMPONENTS INDUSTRIES, LLC, Phoenix, AZ (US)

(72) Inventors: JooYang EOM, Gimpo-si (KR); Inpil YOO, Unterhaching (DE); Seungwon IM, Seoul (KR); ByoungOk LEE, Yeonsu-gu (KR)

(73) Assignee: SEMICONDUCTOR COMPONENTS INDUSTRIES, LLC, Phoenix, AZ (US)

(21) Appl. No.: 16/949,894

(22) Filed: Nov. 19, 2020

(51) Int. Cl. H01L 23/367; H01L 21/48

(52) U.S. Cl. CPC H01L 23/3672; H01L 21/4882

(57) ABSTRACT

In a general aspect, an apparatus can include a metal layer disposed on a surface of the substrate. The apparatus can also include a recess formed in the metal layer and a cooling fin coupled with the metal layer. A portion of the cooling fin can be disposed within the recess.

### TECHNICAL FIELD

This description generally relates to heat transfer technologies for semiconductor device modules. More specifically, the description relates to direct-cooling approaches for semiconductor device modules.

### BACKGROUND

In general, a heatsink, or other heat transfer technologies can transfer heat generated by electronic components included in semiconductor device power module to, for example, surrounding air, and/or a liquid coolant. By transferring or directing heat away from the electronic components, a temperature of the electronic (e.g., semiconductor) components can be maintained at desirable levels (e.g., to prevent overheating). Maintaining the temperature of the electronic components to prevent overheating can also prevent damage to the electronic components and/or power modules including such components. Overheating, and any resulting damage to the electronic components, or the associated power modules (e.g., warpage of a power module), can negatively impact the reliability of those components and modules. Current heat transfer technologies can have certain drawback and/or may not be desirable for certain applications.

### SUMMARY

In one general aspect, an apparatus can include a metal layer disposed on a surface of the substrate. The apparatus can also include a recess formed in the metal layer and a cooling fin coupled with the metal layer. A portion of the cooling fin can be disposed within the recess.

In another general aspect, an apparatus can include a substrate, and a semiconductor die coupled with a first surface of the substrate. The apparatus can further include a metal layer disposed on a second surface of the substrate, the second surface being opposite the first surface. The apparatus can also include a recess formed in the metal layer; and a cooling fin coupled with the metal layer. A portion of the cooling fin can be disposed within the recess.

In another general aspect, a method can include forming a recess in a metal layer disposed on a substrate. The method can further include depositing a thermally conductive adhesive in the recess, and placing a cooling fin in the thermally conductive adhesive. The cooling fin can be placed such that a portion of the cooling fin is disposed in the thermally conductive adhesive disposed in the recess. The method can also include curing the thermally conductive adhesive to couple the cooling fin with the metal layer.

The details of one or more implementations are set forth in the accompanying drawings and the description below. Other features will be apparent from the description and drawings, and from the claims.

### BRIEF DESCRIPTION OF THE DRAWINGS

FIG. 1 is a diagram that schematically illustrates a semiconductor device module substrate with direct-cooling.

FIGS. 2A and 2B are diagrams that illustrate a folded cooling fin.

FIG. 3 is a diagram that illustrates a cooling fin plate.

FIGS. 4 and 5 are diagrams that illustrate respective cooling fin pins.

FIGS. 6A to 6F are diagrams illustrating a manufacturing process for producing a direct-cooled semiconductor device module.

FIGS. 7A to 7F are diagrams illustrating a manufacturing process for producing another direct-cooled semiconductor device module.

FIGS. 8A to 8F are diagrams illustrating a manufacturing process for producing yet another direct-cooled semiconductor device module.

FIG. 9 is a flowchart that illustrates a method for manufacturing the direct-cooled semiconductor device modules described herein.

### DETAILED DESCRIPTION

A semiconductor device module assembly, as described herein, can include one or more semiconductor die encapsulated in a molding material, and a substrate (e.g., a direct-bonded-metal (DBM) substrate) electrically coupled to the semiconductor die (e.g., on a first side of the substrate). At least a portion of the substrate and the semiconductor die can be encapsulated in a molding compound. A heat transfer mechanism (e.g., including one or more cooling fins) can be coupled with a metal layer disposed on the substrate, such as on an opposite side of the substrate from the one or more semiconductor die (e.g., a second side of the substrate). The metal layer can be exposed through the substrate.

A recess (or plurality of recesses) can be formed in the metal layer and the one or more cooling fins can be inset (partially disposed, anchored, etc.) in respective recesses formed in the metal layer. In some implementations, the one or more cooling fins can be thermally coupled (and mechanically coupled) with the metal layer using a thermally conductive adhesive (such as solder, silver sinter, transient liquid phase sinter, thermally conductive epoxy, and so forth) to couple the respective portions of the one or more cooling fins disposed in the one or more recesses.

Implementations of such approaches, such as those described herein, can improve achieve improved cooling performance of semiconductor device modules over current implementations, such as indirect-cooling approaches using a thermal interface material to attach a heat transfer mechanism with a module substrate. For instance, thermal conductivity of implementations of semiconductor device modules (e.g., from junction (e.g., semiconductor die) to a heat transfer mechanism (e.g. cooling fins)) can be increased from a range of 3-6 watts per meter-kelvin (W/mK) to a range of 25-100 W/mK. This can provide a corresponding improvement (reduction) in a junction-to-fin thermal resistance (Rthjf), which is an important criteria to meet high current (e.g., power) and thermal dissipation specifications for certain applications, such as for automotive high power modules (AHPM) for hybrid electric vehicle (HEV) and electric vehicle (EV) markets.

The implementations described herein can also provide improved thermal dissipation performance over current approaches for direct-cooling of semiconductor device modules (modules) (e.g., modules with a heat transfer mechanism coupled with a substrate without use of a thermal interface material). For instance, the approaches described herein can prevent drift (e.g., increases) in Rthjf due to adhesive layer cracks (e.g., due to thermal cycling) that occur in current direct-cooled modules. Such cracks can be prevented using the approaches described herein as a result of improved mechanical integrity of adhesive connections (e.g., fillets) between the metal layer of the substrate and associated cooling fins. Further, the approaches described herein can also achieve a reduction in material costs, e.g., a fifty percent reduction in thermal adhesive material for attaching cooling fins to a substrate of a module, as thermal adhesive and be applied in the recesses, rather than using a wide field (and possibly thicker) adhesive print over the entire (or most of) a substrate metal layer.

Accordingly, the modules described herein can be configured to provide adequate cooling, while meeting size and cost objectives. The heat-transfer mechanisms described herein can provide improved thermal performance over current approaches, which can allow for increased power consumption capability for modules implemented in high-power device applications. For example, high-power device applications can include high power applications greater than, for example, 600 V (e.g., especially when using silicon carbide (SiC) die) and high power applications greater than, for example, 400 V (e.g., when using silicon die). In some implementations, the modules can be included in a variety of applications including, but not limited to, automotive applications (e.g., AHPMs), computer applications, industrial equipment, on-board charging applications, inverter applications, and/or so forth.

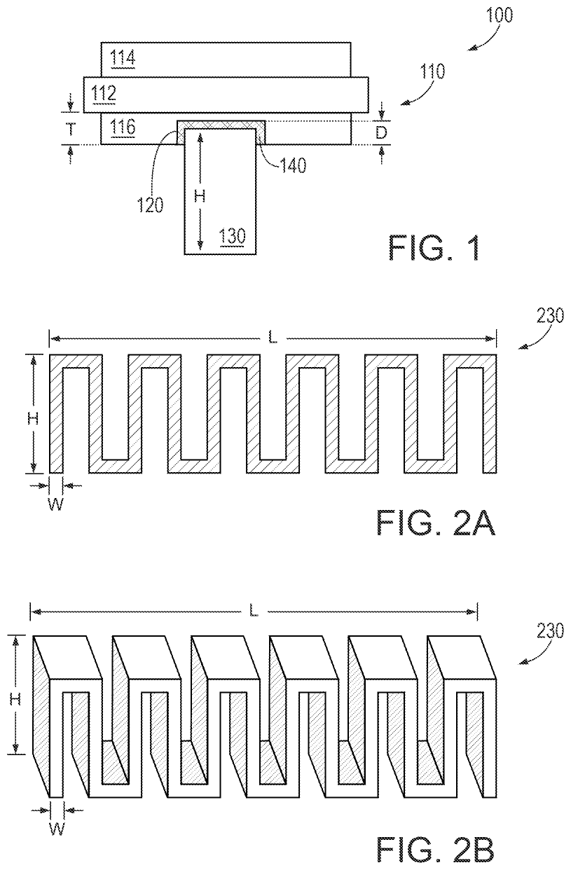

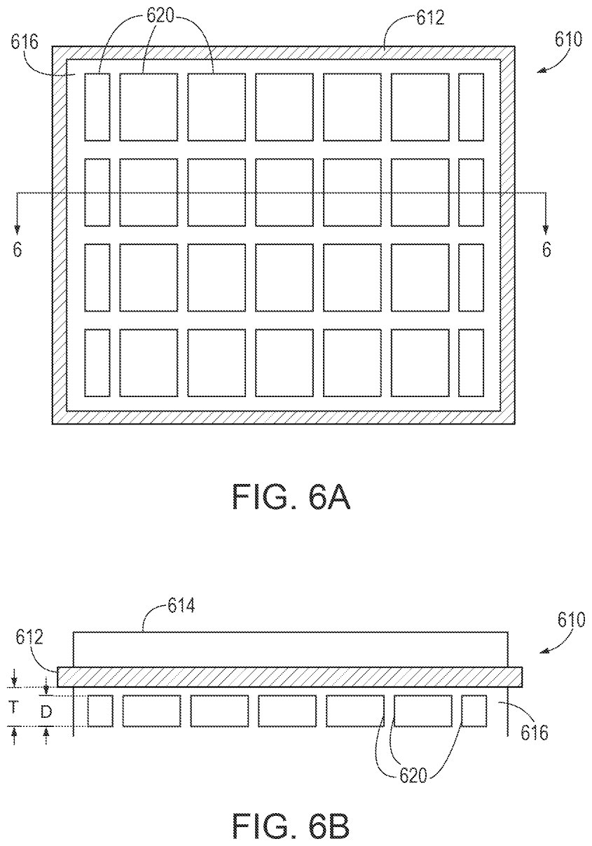

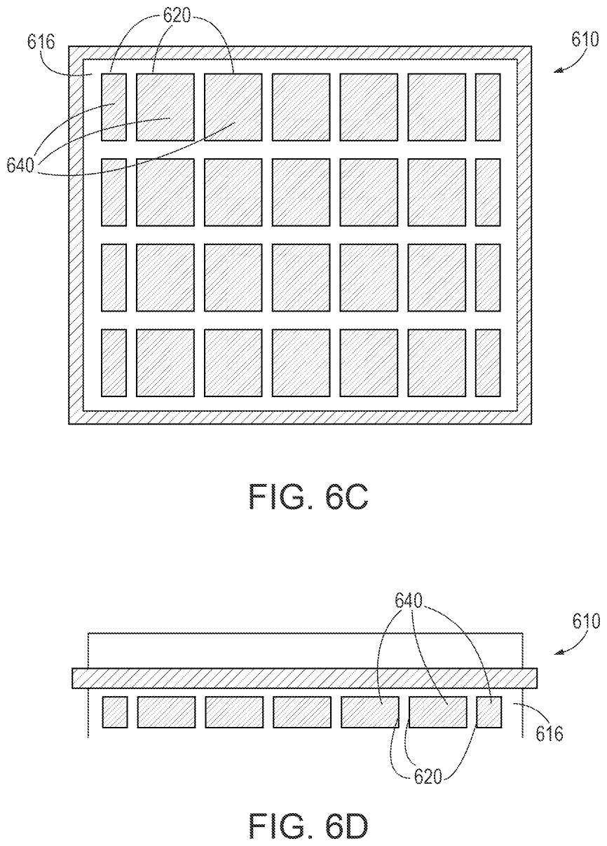

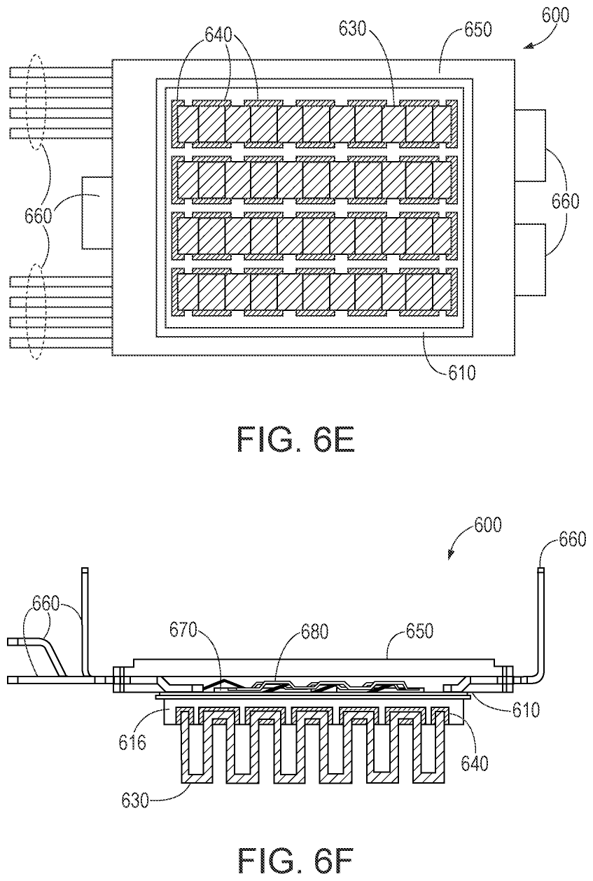

FIG. 1 is a diagram that schematically illustrates a semiconductor device module 100 with direct-cooling. As shown in FIG. 1, the semiconductor device module 100 includes a substrate 110 and a heat transfer mechanism 130 (e.g., one more cooling fins). As FIG. 1 is a schematic diagram given by way of example, for purposes of clarity, FIG. 1 does not illustrate semiconductor die, molding compound, electrical interconnects, power and signal leads, etc. Example implementations of semiconductor device modules (which can implement the schematically illustrated semiconductor device module 100) are shown, in conjunction with associated methods of manufacture, in FIGS. 6A, to 8F.

As shown in FIG. 1, the substrate 110, which can be a direct-bonded metal (DBM) substrate, such as a direct-bonded copper (DBC) substrate, can include a dielectric layer 112, which can be a ceramic or other appropriate material. The substrate 110 can also include a first metal layer 114, which can be a patterned metal layer to which one or more semiconductor die can be coupled. The substrate 110 can also include a second metal layer 116, to which the heat transfer mechanism 130 can be coupled, such as described herein.

As shown in FIG. 1, a recess 120 can be formed in the second metal layer 116. In some implementations, the recess 120 can be formed by etching and/or mechanical grinding, though other approaches are possible. The second metal layer 116 can have a thickness T and the recess 120 can have a depth D in the second metal layer 116. In some implementations, the depth D can be seventy percent (approximately seventy percent) of the thickness T. In some implementations, the thickness T can be in a range of 0.2 to 2 millimeters (mm) and the depth D can be in a range 0.14 to 1.4 mm.

In the semiconductor device module 100, the heat transfer mechanism 130 is coupled with the second metal layer 116 using a thermally conductive adhesive 140. In some implementations, the thermally conductive adhesive 140 can include one or more of solder, silver sinter, metal filled epoxy, transient liquid phase sinter (TLPS), and so forth. The particular thermally conductive adhesive 140 used will depend on the particular implementation. Such approaches can provided the benefits noted above, e.g., due to improved mechanical integrity of connection (bond, fillet, etc.) between the second metal layer 116 and the heat transfer mechanism 130 (e.g., formed by the thermally conductive adhesive 140).

As shown in FIG. 1, the heat transfer mechanism 130 can have a height H, which depend on the particular implementation. In some implementations, the height H can be in a range of 6 to 10 mm. In the drawings, dimensions shown in one figure may also be shown in other figures for purposes of reference. However, such dimensions may not be specifically discussed with respect to each figure in which they are indicated.

FIGS. 2A-5 illustrate example cooling fins (heat transfer mechanisms) that can be used to implement, e.g., the heat transfer mechanism 130 of FIG. 1. The cooling fin implementations shown in FIGS. 2A-5 are given by way of example, and cooling fins having other configurations are possible. Also, depending on the particular implementation, the cooling fins of FIGS. 2A-5 (or other cooling fins) can be formed of a thermally conductive material, such as copper (e.g., a copper, or other metal sheet, a metal bar, thermally conductive polymers, thermally conductive ceramics, etc.). However, for clarity, and purposes of illustration, the cooling fins of FIGS. 2A-5 are described as being formed of metal (e.g., copper or other metal).

FIGS. 2A and 2B are diagrams that illustrate a folded cooling fin 230. Specifically, FIG. 2A illustrates a side view of the folded cooling fin 230 and the FIG. 2B illustrates an isometric view of the folded cooling fin 230. In some implementations, the folded cooling fin 230 can be formed from a copper sheet (or other metal sheet) that is folded (e.g., using a stamping, or other metal working process). As shown in FIGS. 2A and 2B, a sheet used to form the folded cooling fin 230 can have a thickness W, which can be in a range of 2 mm, though other thicknesses (thinner or thicker) are possible. The folded cooling fin 230 can also have a height H (such as shown in FIG. 1) and a length L (e.g., which, in some implementations, can be in a range of 6 to 10 mm). Again, the exact dimensions of the folded cooling fin 230 will depend on the particular implementation. An example implementation of a semiconductor device module including an implementation of the folded cooling fin 230 is shown in FIGS. 6E and 6F (in connection with the manufacturing process of FIGS. 6A-6F).

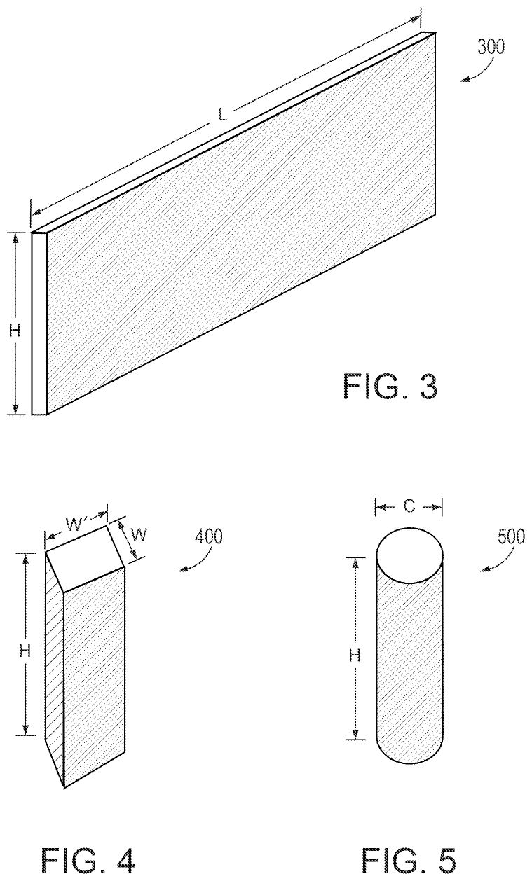

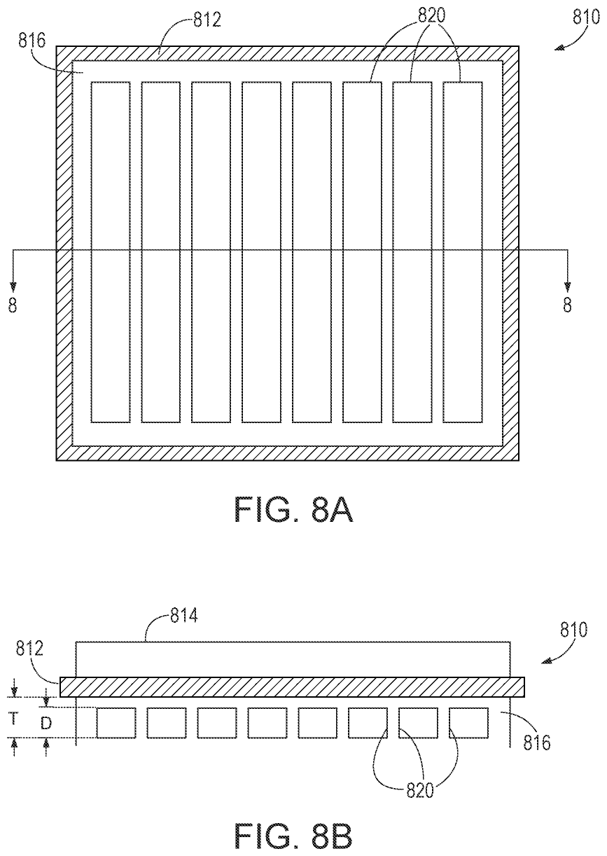

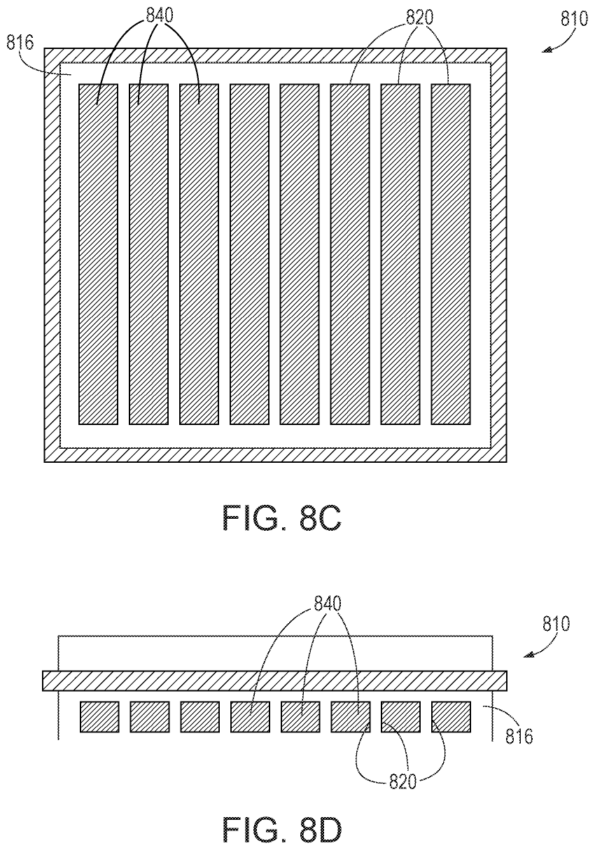

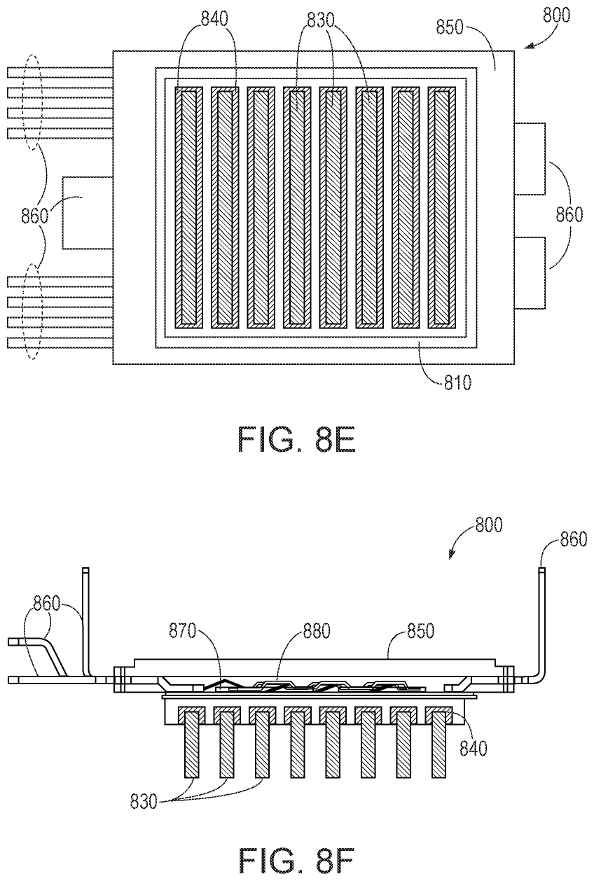

FIG. 3 is a diagram that illustrates an isometric view of a cooling fin plate 330. In some implementations, as with the folded cooling fin 230, the cooling fin plate 330 can be formed from a metal sheet (or other metal sheet), e.g., using a stamping, or other metal working process. As shown in FIG. 3, the sheet used to form the cooling fin plate 330 can have a thickness W (such as shown in FIG. 2), which can be in a range of 2 mm, though other thicknesses (thinner or thicker) are possible. The cooling fin plate 330 can also have a height H (such as shown in FIG. 1) and the length L (e.g., which, in some implementations, can be in a range of 30 to 40 mm). Again, the exact dimensions of the cooling fin plate 330 will depend on the particular implementation. An example implementation of a semiconductor device module including an implementation of the cooling fin plate 330 is shown in FIGS. 8E and 8F (in connection with the manufacturing process of FIGS. 8A-8F).

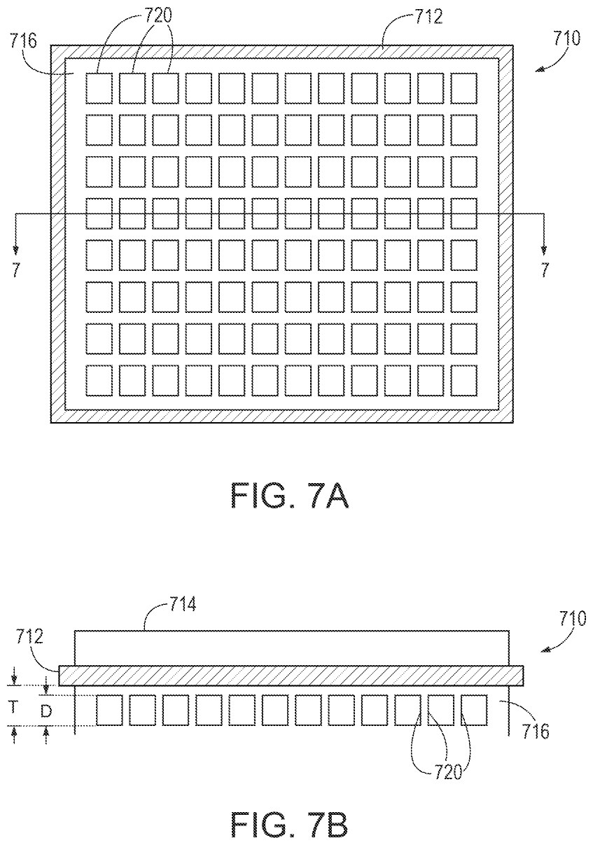

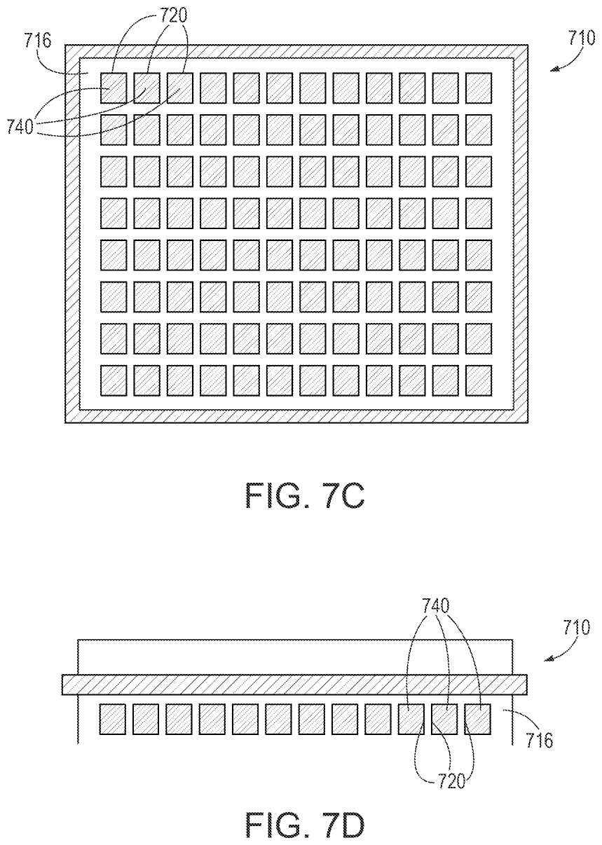

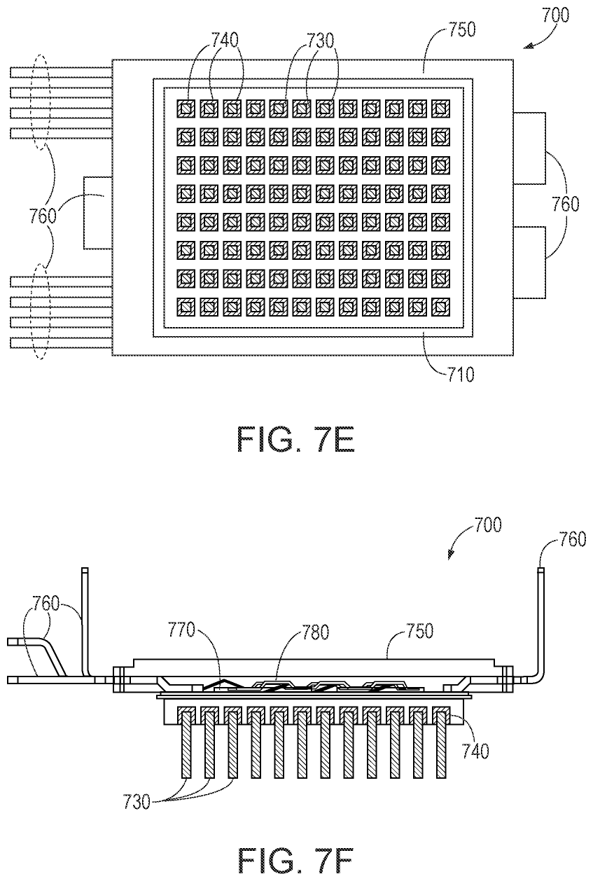

FIGS. 4 and 5 are diagrams that illustrate respective cooling fin pins. Specifically, FIG. 4 illustrates a cooling fin pin 400 with a rectangular cross section having dimensions W (such as the thickness W shown in FIGS. 2 and 3) and W′. In some implementations, the cooling fin pin 400 can have a square cross section (e.g., W and W′ are equal). In some implementations, W and W′ for the cooling fin pin 400 can be in a range of 30 to 40 mm. FIG. 5 illustrates a cooling fin pin 500 with a circular cross section having a diameter C, which can be in a same range as the cross sectional dimensions of the cooling fin pin 400. In some implementations, the cooling fin pins 400 and 500 can be formed from metal stock (e.g., a metal sheet, bar stock), e.g., using a stamping process, or other metal working process. As illustrated in FIGS. 4 and 5, the cooling fin pin 400 and the cooling fin pin 500 can also have a height H (such as shown in FIG. 1). An example implementation of a semiconductor device module including an implementation of cooling fin pins (e.g., with a square cross section) is shown in FIGS. 7E and 7F (in connection with the manufacturing process of FIGS. 7A-7F).

FIGS. 6A to 6F are diagrams illustrating a manufacturing process for producing a direct-cooled semiconductor device module (e.g., a semiconductor device module 600 shown in FIGS. 6E and 6F), which can be an implementation of the semiconductor device module 100 including at least one folded cooling fin, such as the folded cooling fin 230. Referring to FIG. 6A, a substrate 610 (e.g., a DBM substrate) is shown. The substrate 610 includes a metal layer 616 disposed on a dielectric layer 612. As shown in a FIG. 6A, a plurality of recesses 620 are formed (e.g., etched, ground, etc.) in the metal layer 616. With further reference to FIG. 1, the recesses 620 can correspond with the recess 120 (e.g., can have a depth D in the metal layer 616, which can have a thickness T). It is noted that the pattern of the recesses 620 in FIG. 6A can correspond with a footprint of a folded cooling fin (e.g., the folded cooling fin 230). That is, the pattern of the recesses 620 can be configured to receive respective portions of a folded cooling fin that are to be coupled (e.g., using a thermal adhesive) to the metal layer 616. Also shown in FIG. 6A is a section line 6-6, which corresponds with the cross-sectional views of FIGS. 6B, 6D and 6F.

For instance, FIG. 6B is a diagram that illustrates a cross-sectional view of the substrate 610 of FIG. 6A along the section line 6-6. As can be seen in FIG. 6B, the recesses 620 can have a depth D in the metal layer 616, which can have a thickness T, such as described above with respect to FIG. 6A. As also shown in FIG. 6B, the substrate 610 can include a metal layer 614, which can be a patterned metal layer. In some implementations, such as this example, one or more semiconductor die can be coupled (electrically coupled) to the metal layer 614, such as shown in FIG. 6F.

Referring now to FIGS. 6C and 6D, a thermally conductive adhesive 640 can be disposed in the recesses 620 in the metal layer 616. In this example, FIG. 6D illustrates a cross-sectional view of the substrate 610, as shown in FIG. 6C, along a section line corresponding with the section line 6-6 of FIG. 6A. In some implementations, the thermally conductive adhesive 640 can be deposited using a printing process (e.g., solder print, adhesive print, etc.). It is noted that, in this implementation, the thermally conductive adhesive 640 is disposed in the recesses 620 and omitted on other portions of the metal layer 616. As noted above, such approaches can reduce an amount of the thermally conductive adhesive 640 used (e.g., by approximately fifty percent), as compared to implementations where thermally conductive adhesive is applied across all (or most) of a metal layer without the recesses 620.

As illustrated in FIGS. 6E and 6F (where FIG. 6F is a cross-sectional view of the semiconductor device module 600 along a section line corresponding with the section line 6-6 of FIG. 6A), producing the semiconductor device module 600 can include coupling one more semiconductor die 670 with the substrate 610 (e.g., with the metal layer 614). As further shown in the FIGS. 6E and 6F, producing the semiconductor device module 600 can further include attaching signal and power terminals (terminals 660), and forming electrical interconnects 680 between the terminals 660 and the one more semiconductor die 670, and/or between the one or more semiconductor die 670. The electrical interconnects 680 can include wire bonds, conductive clips, etc. As also illustrated in FIGS. 6E and 6F, producing the semiconductor device module 600 can include forming a molding compound 650 that can encapsulate portions of the semiconductor device module 600, such as shown in FIG. 6F.

Producing the semiconductor device module 600 can also include, as shown in FIGS. 6E and 6F, coupling a plurality of folded cooling fins 630 to the metal layer 616 with the thermally conductive adhesive 640. For purposes of illustration, the metal layer 616, the folded cooling fins 630 and the thermally conductive adhesive 640 are shown enlarged (e.g., not to scale with other elements of the semiconductor device module 600). In some implementations, the folded cooling fins 630 can be held in a tool (e.g., jig, etc.) and placed in the thermally conductive adhesive 640 disposed in the recesses 620 (e.g., such as in the arrangement shown in FIG. 6F). A curing operation (bake, sinter, solder reflow, etc.) can then be performed to couple (fix, attach, etc.) the folded cooling fins 630 with the metal layer 616 with the cured thermally conductive adhesive 640.

FIGS. 7A to 7F are diagrams illustrating a manufacturing process for producing a direct-cooled semiconductor device module (e.g., a semiconductor device module 700 shown in FIGS. 7E and 7F), which can be an implementation of the semiconductor device module 100 including at least one cooling fin pin, such as the cooling fin pin 400 or the cooling fin pin 500. Referring to FIG. 7A, a substrate 710 (e.g., a DBM substrate) is shown. The substrate 710 includes a metal layer 716 disposed on a dielectric layer 712. As shown in a FIG. 7A, a plurality of recesses 720 are formed (e.g., etched, ground, etc.) in the metal layer 716. With further reference to FIG. 1, the recesses 720 can correspond with the recess 120 (e.g., can have a depth D in the metal layer 716, which can have a thickness T). It is noted that the size and shape of the recesses 720 in FIG. 7A can correspond with a footprint (cross section) of a cooling fin pin (e.g., the cooling fin pin 400 or the cooling fin pin 500). That is, the recesses 720 can be configured to receive respective portions of cooling fin pins that are to be coupled (e.g., using a thermal adhesive) to the metal layer 716. Also shown in FIG. 7A is a section line 7-7, which corresponds with the cross-sectional views of FIGS. 7B, 7D and 7F.

For instance, FIG. 7B is a diagram that illustrates a cross-sectional view of the substrate 710 of FIG. 7A along the section line 7-7. As can be seen in FIG. 7B, the recesses 720 can have a depth D in the metal layer 716, which can have a thickness T, such as described above with respect to FIG. 7A. As also shown in FIG. 7B, the substrate 710 can include a metal layer 714, which can be a patterned metal layer. In some implementations, such as this example, one or more semiconductor die can be coupled (electrically coupled) to the metal layer 714, such as shown in FIG. 7F.

Referring now to FIGS. 7C and 7D, a thermally conductive adhesive 740 can be disposed in the recesses 720 in the metal layer 716. In this example, FIG. 7D illustrates a cross-sectional view of the substrate 710, as shown in FIG. 7C, along a section line corresponding with the section line 7-7 of FIG. 7A. In some implementations, the thermally conductive adhesive 740 can be deposited using a printing process (e.g., solder print, adhesive print, etc.). It is noted that, in this implementation, the thermally conductive adhesive 740 is disposed in the recesses 720 and omitted on other portions of the metal layer 716. As noted above, such approaches can reduce an amount of the thermally conductive adhesive 740 used (e.g., by approximately fifty percent), as compared to implementations where thermally conductive adhesive is applied across all (or most) of a metal layer without the recesses 720.

As illustrated in FIGS. 7E and 7F (where FIG. 7F is a cross-sectional view of the semiconductor device module 700 along a section line corresponding with the section line 7-7 of FIG. 7A), producing the semiconductor device module 700 can include coupling one more semiconductor die 770 with the substrate 710 (e.g., with the metal layer 714). As further shown in the FIGS. 7E and 7F, producing the semiconductor device module 700 can further include attaching signal and power terminals (terminals 760), and forming electrical interconnects 780 between the terminals 760 and the one more semiconductor die 770, and/or between the one or more semiconductor die 770. The electrical interconnects 780 can include wire bonds, conductive clips, etc. As also illustrated in FIGS. 7E and 7F, producing the semiconductor device module 700 can include forming a molding compound 750 that can encapsulate portions of the semiconductor device module 700, such as shown in FIG. 7F.

Producing the semiconductor device module 700 can also include, as shown in FIGS. 7E and 7F, coupling a plurality of cooling fin pins 730 to the metal layer 716 with the thermally conductive adhesive 740. For purposes of illustration, the metal layer 716, the cooling fin pins 730 and the thermally conductive adhesive 740 are shown enlarged (e.g., not to scale with other elements of the semiconductor device module 700). In some implementations, the cooling fin pins 730 can be held in a tool (e.g., jig, etc.) and placed in the thermally conductive adhesive 740 disposed in the recesses 720 (e.g., such as in the arrangement shown in FIG. 7F). A curing operation (bake, sinter, solder reflow, etc.) can then be performed to couple (fix, attach, etc.) the cooling fin pins 730 with the metal layer 716 with the cured thermally conductive adhesive 740.

FIGS. 8A to 8F are diagrams illustrating a manufacturing process for producing a direct-cooled semiconductor device module (e.g., a semiconductor device module 800 shown in FIGS. 8E and 8F), which can be an implementation of the semiconductor device module 100 including at least one cooling fin plate, such as the cooling fin plate 300. Referring to FIG. 8A, a substrate 810 (e.g., a DBM substrate) is shown. The substrate 810 includes a metal layer 816 disposed on a dielectric layer 812. As shown in a FIG. 8A, a plurality of recesses 820 are formed (e.g., etched, ground, etc.) in the metal layer 816. With further reference to FIG. 1, the recesses 820 can correspond with the recess 120 (e.g., can have a depth D in the metal layer 816, which can have a thickness T). It is noted that the size and shape of the recesses 820 in FIG. 8A can correspond with a footprint (cross section) of a cooling fin plate (e.g., the cooling fin plate 300). That is, the recesses 820 can be configured to receive respective portions of cooling fin plates that are to be coupled (e.g., using a thermal adhesive) to the metal layer 816. Also shown in FIG. 8A is a section line 8-8, which corresponds with the cross-sectional views of FIGS. 8B, 8D and 8F.

For instance, FIG. 8B is a diagram that illustrates a cross-sectional view of the substrate 810 of FIG. 8A along the section line 8-8. As can be seen in FIG. 8B, the recesses 820 can have a depth D in the metal layer 816, which can have a thickness T, such as described above with respect to FIG. 8A. As also shown in FIG. 8B, the substrate 810 can include a metal layer 814, which can be a patterned metal layer. In some implementations, such as this example, one or more semiconductor die can be coupled (electrically coupled) to the metal layer 814, such as shown in FIG. 8F.

Referring now to FIGS. 8C and 8D, a thermally conductive adhesive 840 can be disposed in the recesses 820 in the metal layer 816. In this example, FIG. 8D illustrates a cross-sectional view of the substrate 810, as shown in FIG. 8C, along a section line corresponding with the section line 8-8 of FIG. 8A. In some implementations, the thermally conductive adhesive 840 can be deposited using a printing process (e.g., solder print, adhesive print, etc.). It is noted that, in this implementation, the thermally conductive adhesive 840 is disposed in the recesses 820 and omitted on other portions of the metal layer 816. As noted above, such approaches can reduce an amount of the thermally conductive adhesive 840 used (e.g., by approximately fifty percent), as compared to implementations where thermally conductive adhesive is applied across all (or most) of a metal layer without the recesses 820.

As illustrated in FIGS. 8E and 8F (where FIG. 8F is a cross-sectional view of the semiconductor device module 800 along a section line corresponding with the section line 8-8 of FIG. 8A), producing the semiconductor device module 800 can include coupling one more semiconductor die 870 with the substrate 810 (e.g., with the metal layer 814). As further shown in the FIGS. 8E and 8F, producing the semiconductor device module 800 can further include attaching signal and power terminals (terminals 860), and forming electrical interconnects 880 between the terminals 860 and the one more semiconductor die 870, and/or between the one or more semiconductor die 870. The electrical interconnects 880 can include wire bonds, conductive clips, etc. As also illustrated in FIGS. 8E and 8F, producing the semiconductor device module 800 can include forming a molding compound 850 that can encapsulate portions of the semiconductor device module 800, such as shown in FIG. 8F.

Producing the semiconductor device module 800 can also include, as shown in FIGS. 8E and 8F, coupling a plurality of cooling fin plates 830 to the metal layer 816 with the thermally conductive adhesive 840. For purposes of illustration, the metal layer 816, the cooling fin plates 830 and the thermally conductive adhesive 840 are shown enlarged (e.g., not to scale with other elements of the semiconductor device module 800). In some implementations, the cooling fin plates 830 can be held in a tool (e.g., jig, etc.) and placed in the thermally conductive adhesive 840 disposed in the recesses 820 (e.g., such as in the arrangement shown in FIG. 8F). A curing operation (bake, sinter, solder reflow, etc.) can then be performed to couple (fix, attach, etc.) the cooling fin plates 830 with the metal layer 816 with the cured thermally conductive adhesive 840.

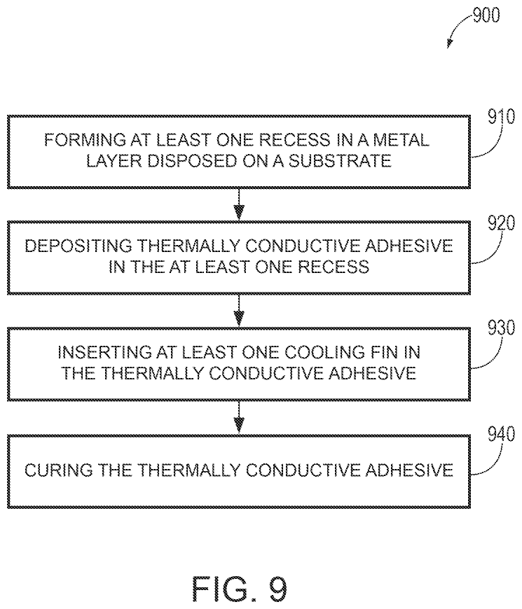

FIG. 9 is a flowchart that illustrates a method 900 for manufacturing the direct-cooled semiconductor device modules described herein. For instance, implementations of the method 900 can be used to produce the semiconductor device modules 600, 700 and 800. The method 900 includes, at block 910, forming at least one recess in a metal layer disposed on a substrate (e.g., a DBM substrate). At block 920, the method 900 includes depositing a thermally conductive adhesive in the at least one recess. At block 930, the method 900 includes inserting (setting, placing, etc.) at least one cooling fin (e.g., a portion of a cooling fin) in the thermally conductive adhesive. At block 940, the method 900 includes curing the thermally conductive adhesive, e.g., to couple the at least one cooling fin with the metal layer.

It will be understood that, in the foregoing description, when an element is referred to as being on, connected to, electrically connected to, coupled to, thermally coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Implementations of the various techniques described herein may be implemented in (e.g., included in) digital electronic circuitry, or in computer hardware, firmware, software, or in combinations of them. Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An apparatus, comprising:
a substrate;
a metal layer disposed on a surface of the substrate;
a recess formed in the metal layer; and
a cooling fin coupled with the metal layer, a portion of the cooling fin being disposed within the recess.

2. The apparatus of claim 1, wherein:
the metal layer has a thickness; and
the recess has a depth in the metal layer, the depth being less than the thickness.

3. The apparatus of claim 2, wherein the depth is seventy percent of the thickness.

4. The apparatus of claim 2, wherein:
the thickness is in a range of 0.2 to 2 millimeters (mm); and
the depth is in a range of 0.14 to 1.4 mm.

5. The apparatus of claim 1, wherein the recess is a first recess and the cooling fin is a folded cooling fin, the apparatus further comprising:
one or more other recesses formed in the metal layer, respective portions of the folded cooling fin being disposed in the one or more other recesses and coupled with the metal layer.

6. The apparatus of claim 1, wherein the recess is a first recess and the cooling fin is a first cooling fin, the apparatus further comprising:
a second recess formed in the metal layer; and
a second cooling fin coupled with the metal layer, a portion of the second cooling fin being disposed within the second recess.

7. The apparatus of claim 6, wherein:
the first cooling fin is a first cooling fin pin; and
the second cooling fin is a second cooling fin pin.

8. The apparatus of claim 6, wherein:
the first cooling fin is a first cooling fin plate; and
the second cooling fin is a second cooling fin plate.

9. The apparatus of claim 1, further comprising a thermally conductive adhesive disposed in the recess, the thermally conductive adhesive thermally coupling the cooling fin to the metal layer.

10. An apparatus, comprising:
a substrate;
a semiconductor die coupled with a first surface of the substrate;
a metal layer disposed on a second surface of the substrate, the second surface being opposite the first surface;
a recess formed in the metal layer; and
a cooling fin coupled with the metal layer, a portion of the cooling fin being disposed within the recess.

11. The apparatus of claim 10, further comprising a thermally conductive adhesive disposed in the recess, the thermally conductive adhesive thermally coupling the cooling fin to the metal layer, the thermally conductive adhesive including at least one of solder, epoxy, or sinter.

12. The apparatus of claim 10, wherein:
the metal layer has a thickness; and
the recess has a depth in the metal layer, the depth being seventy percent of the thickness.

13. The apparatus of claim 12, wherein the thickness is in a range of 0.2 to 2 millimeters.

14. The apparatus of claim 10, wherein the recess is a first recess and the cooling fin is a folded cooling fin, the apparatus further comprising:
one or more other recesses formed in the metal layer, respective portions of the folded cooling fin being disposed in the one or more other recesses and coupled with the metal layer.

15. The apparatus of claim 10, wherein the recess is a first recess and the cooling fin is a first cooling fin, the apparatus further comprising:
a second recess formed in the metal layer; and
a second cooling fin coupled with the metal layer, a portion of the second cooling fin being disposed within the second recess.

16. The apparatus of claim 15, wherein:
the first cooling fin is a first cooling fin pin; and
the second cooling fin is a second cooling fin pin.

17. The apparatus of claim 15, wherein:
the first cooling fin is a first cooling fin plate; and
the second cooling fin is a second cooling fin plate.

18. A method comprising:
forming a recess in a metal layer disposed on a substrate;
depositing a thermally conductive adhesive in the recess;
placing a cooling fin in the thermally conductive adhesive, such that a portion of the cooling fin is disposed in the thermally conductive adhesive disposed in the recess; and
curing the thermally conductive adhesive to couple the cooling fin with the metal layer.

19. The method of claim 18, wherein the metal layer has a thickness, and the forming the recess in the metal layer includes etching the recess to a depth in the metal layer, the depth being less than the thickness.

20. The method of claim 18, wherein the recess is a first recess, the method further comprising:
forming at least one other recess;
depositing the thermally conductive adhesive in the at least one other recess; and
prior to curing the thermally conductive adhesive, placing a respective cooling fin in the thermally conductive adhesive in the at least one other recess, such that a portion of the respective cooling fin is disposed in the thermally conductive adhesive disposed in the at least one other recess.
